(19) United States
(12) Patent Application Publication
(10) Pub. No.: US 2013/0221976 A1
(43) Pub. Date: Aug. 29, 2013

(54) MONITORING A POWER SUPPLY LINE SUPPLIED AT ONE END FOR GROUND FAULTS

(71) Applicants: Joerg Blumschein, Berlin (DE); Cezary Dzienis, Dallgow-Doeberitz (DE); Matthias Kereit, Berlin (DE)

(72) Inventors: Joerg Blumschein, Berlin (DE); Cezary Dzienis, Dallgow-Doeberitz (DE); Matthias Kereit, Berlin (DE)

(73) Assignee: SIEMENS AKTIENGESELLSCHAFT, MUENCHEN (DE)

(21) Appl. No.: 13/883,082

(22) PCT Filed: Nov. 5, 2010
(86) PCT No.: PCT/EP2010/066919

§ 371 Date: May 2, 2013

(51) Int. Cl. G01R 31/02

(52) U.S. Cl. CPC G01R 31/025
USPC 324/509

(57) ABSTRACT

A method and a protective device for monitoring a power supply line supplied at one end in a three-phase electrical power supply system with regard to the presence of a ground fault. The power supply line is connected, at the end thereof remote from the supply, to a transformer operated in a star-delta connection. When a coupling effect according to Bauch's paradox occurs, the ground fault is reliably and selectively disconnected by determining the phase currents in the individual phase conductors of the power supply line and the zero phase sequence system current at a measuring point which is at that end of the power supply line remote from the supply. A suspected ground fault signal is generated if the individual phase currents and the zero phase sequence system current are substantially of the same magnitude and are in phase. The suspected ground fault signal is used during further monitoring with regard to the presence of the ground fault.

The invention relates to a method for monitoring a power supply line supplied at one end of a three-phase electrical power supply network in respect of the presence of a short circuit to ground, wherein the power supply line is connected, at the end thereof remote from the supply, to a transformer operated in a star-delta connection. The invention also relates to an electrical protection device with which corresponding monitoring can be carried out.

Such power supply lines supplied at one end, i.e. power supply lines which are only connected at one end to an electrical power source which supplies electrical power to the line and which are connected at the other end to a transformer operated in a star-delta connection, are not unusual in electrical power supply networks. Such network configurations occur for example in what are referred to as spur lines or in radial networks.

Electrical protection devices are used in order to protect the power supply line and further primary components connected thereto (e.g. the transformer) against high loads as a result of short circuits. To do this such protection devices usually pick up measured values which represent current and voltage at a measuring point of the power supply line and investigate said values, using so-called protection algorithms, for states which indicate a short circuit on the power supply line.

In the configuration described, with a power supply line supplied at one end, which is operated at its other end with a transformer operated in a star-delta connection, an effect can be observed with a single-pole or two-pole short-to-ground, which is referred to in technical literature as “Bauch's paradox”.

In this paradox a single-pole or two-pole short-to-ground also acts via the magnetic coupling of the transformer on the actual “sound” phase conductor of the power supply line, i.e. the phase conductor not affected by the short-to-ground, so that there is a danger of an electrical protection device, because of the currents and voltages picked up at a measuring point, making incorrect decisions and performing an unwanted switch-off of correctly-functioning phase conductors.

Frequently electrical protection devices are used for monitoring electric power supply lines which operate on the distance protection principle. In such cases a deduction is made about the presence of short circuits and shorts-to-ground on the basis of impedances of the individual conductor-conductor loops and conductor-ground loops. In the case of Bauch's paradox in particular the determination of the loops affected by the error and the direction in which the short-to-ground lies, seen from the protection device, are adversely affected, since for example in a two-pole short-to-ground the impedance in the phase-phase loop can no longer be detected by measuring technology, because the difference between the currents in the phases affected by the error amounts to zero. In addition it can occur that the direction measurement algorithm for a phase-ground loop detects a forwards direction while a backwards direction is detected for the other phase-ground loop. With single-pole shorts to ground too, when the usual direction measurement algorithm is used, incorrect direction decisions are output. In addition all three phase conductors are frequently switched off although the short-to-ground only relates to one phase conductor.

Usually, to resolve this problem, a further protection device, which carries out monitoring of the power supply line in accordance with the overcurrent protection method or time overcurrent protection method (“UMZ (definite time overcurrent protection) characteristic” or “AMZ (indefinite time overcurrent protection) characteristic”), is provided as backup protection. The short-to-ground protection of a reserve protection device operating in this way has the disadvantage of being significantly slower than a distance protection algorithm. In addition the time overcurrent protection on the one hand does not always operate phase-selectively and on the other hand does not operate line-selectively at all.

The underlying object of the present invention is therefore to specify a method for monitoring a power supply line of the type described at the start and also a corresponding protection device with which a reliable and selective disconnection of a short-to-ground can be undertaken even if a coupling effect in accordance with Bauch's paradox occurs.

To achieve this object, in accordance with the invention, a method of the type stated at the start is embodied such that, at a measuring point which lies at the end of the power supply line remote from the supply, the phase currents in the individual phase conductors of the power supply line as well as the zero sequence current will be determined, a suspected short-to-ground signal will be generated if the individual phase currents and the zero sequence current are essentially of the same magnitude and are in phase, and the suspected short-to-ground signal will be included in the further monitoring in respect of the presence of the short-to-ground.

This solution is based on the knowledge that, in Bauch's paradox, the coupling of the error effect by the transformer is essentially to be attributed to a strong zero sequence component which generates a circulating current flow on the secondary side of the transformer which couples back equally to all three phase conductors of the primary side. To investigate whether the effect of Bauch's paradox is present in the event of an actual error, in accordance with the invention, the investigation of the phase conductor currents and of the zero sequence current at the measuring point which is located on the primary side of the transformer is therefore proposed, to the extent of whether the phase conductor currents and the zero sequence current essentially—i.e. ignoring deviations conditional on the measurement technology—are of the same magnitude and have a matching phase angle. A positive recognition of the presence of the effect in accordance with Bauch's paradox is indicated in the form of the suspected short-to-ground signal, which is accordingly included in the further specification of the error.

In order to specify a simple possibility for numerical detection of the presence of Bauch's paradox in a protection device, in accordance with an advantageous embodiment of the inventive method it is proposed in concrete terms that the positive sequence current and the negative sequence current also be determined at the measuring point and the zero sequence current be compared on the one hand with the positive sequence current and on the other hand with the negative sequence current and a first indicator signal be formed if the zero sequence current exceeds both the positive sequence current and also the negative sequence current by a predetermined factor. In addition the zero sequence current is also compared to the individual phase currents and a second indicator signal is formed if the zero sequence current and the individual phase currents are roughly of the same magnitude, and the suspected short-to-ground signal is generated if both the first indicator signal and also the second indicator signal are present.

The advantage of this embodiment is that a complex investigation of the phase angle of the individual phase currents and the zero sequence current can be dispensed with, since the matching phase angle can be checked in this case by comparing the zero sequence, negative sequence and positive sequence components of the currents at the measuring point. In respect of the investigation of the size of the individual phase currents and the zero sequence current an observation can then take place based on amplitudes of the individual currents, through which the algorithm can be greatly simplified.

A further advantageous embodiment of the inventive method makes provision that, if a suspected short-to-ground signal for determining the phase conductor affected by the short-to-ground is present, a comparison of the pointers is carried out for the positive sequence voltage at the measuring point and the negative sequence voltage at the measuring point, and an error type signal indicating a two-pole short-to-ground is formed if the phase angles enclosed by these pointers amounts to around 0°, 120° or 240°, and otherwise a second error type signal is formed which points to a single-pole short-to-ground.

In this way the error type of the short-to-ground can be determined in a very reliable manner, i.e. whether a single-pole error or a two-pole error is involved. With this information a subsequent recognition of the error loop affected by the short-to-ground can be significantly facilitated.

Since variations in measurement technology mean that the ideal phase difference of 0°, 120° or 240° will never occur exactly, it is proposed that the first error type signal is also formed when the phase angle enclosed by the pointers for the positive sequence voltage and the negative sequence voltage deviates from a trigger threshold value of 0°, 120° or 240°, wherein the trigger threshold value depends dynamically on the level of the positive sequence voltage and the negative sequence voltage. In accordance with a further advantageous embodiment, to detect the error loop actually affected by the short-to-ground, there can be provision that, if the first error type signal is present, the chained phase voltages of the individual phase conductors are compared with one another and a first loop selection signal is formed, which specifies those phase conductors which together form the lowest chained phase voltage as is affected by a two-pole short-to-ground, and if a second error type signal is present, the phase-ground voltages of the individual phase conductors are compared and a second loop selection signal is formed having those phase conductors which exhibit the lowest phase-ground voltage as affected by a single-pole short-to-ground.

Through this, because of comparatively simple-to-check conditions related to the chained phase voltages—i.e. the conductor-conductor voltages existing in each case between the individual phase conductors—or at the respective phase-ground voltages, a detection of the error loop involved is carried out.

A further advantageous embodiment of the inventive method also makes provision that, to detect the direction in which the short-to-ground lies in relation to the measuring point, the negative zero sequence current pointer and the associated zero sequence voltage pointer are compared and a forward signal specifying a short-to-ground in the forward direction is created if the zero sequence voltage pointer lags behind the negative zero sequence current pointer by a phase angle with a prespecified difference value.

This enables a check to be made as to whether, seen from the protection device, the short-to-ground lies on the monitored power supply line (in the forwards direction) or outside the power supply line (in the backwards action). Since two-pole shorts-to-ground can be jointly assessed on the basis of the zero sequence current and the zero sequence voltage, an inconsistent decision about the error direction is prevented.

A further advantageous embodiment of the inventive method also makes provision that, if a forwards signal is present, an error signal is generated which causes the phase conductor affected by the short-to-ground in each case to be switched off.

In this way, especially with single-pole short circuits, the phase conductor actually affected by the error can be selectively switched off in each case, but the sound phase conductors remain switched on.

In accordance with a further advantageous embodiment of the inventive method there is provision that, for a phase conductor ground loop affected by the short-to-ground, an impedance pointer is defined and the location of the impedance pointer in a predetermined excitation region in the complex number plane is investigated, a confirmation signal is generated if the impedance point lies in the excitation region and the error signal for switching off the phase conductor affected by the short-to-ground is only created if the confirmation signal is also present.

In this way an impedance-based checking of the loop affected by the error can additionally be carried out in order to increase the security of the error detection even further.

A further advantageous embodiment of the inventive method also makes provision for the method to be carried out by a distance protection device, which carries out monitoring of the power supply line using an error detection algorithm in the form of a distance protection, and if the suspected short-to-ground is present, detection algorithms for detecting a loop affected by an error and an error direction, usually executed as part of the error detection algorithm executed by the distance protection device, are blocked.

In this way the inventive method can be advantageously implemented in a distance protection device which is usually configured in any event to determine the measured values needed. In order, in the event of the presence of Bauch's paradox, to improve unreliable behavior of the error detection in accordance with the conventional distance protection principle, on positive detection of Bauch's paradox, i.e. if a suspected short-to-ground signal is present, the algorithms usually executed within the framework of the distance protection are blocked for loop selection and for direction detection and replaced by correspondingly adapted algorithms, as described here.

In respect of the protection device the above object is achieved by an electric protection device for monitoring a power supply line of a three-phase electrical power supply network supplied on one side with respect to the presence of a short-to-ground, wherein the power supply line is connected at the end thereof remote from the supply to a transformer operated in a star-delta connection. The protection device has a measuring device for detection of phase currents and phase voltages at a measuring point which lies at the end of the power supply line remote from the supply and a data processing device which is configured for processing the phase currents and phase voltages.

Inventively there is provision for the data processing device to be configured for carrying out the method in accordance with one of the preceding embodiments.

The invention will be explained below in greater detail on the basis of exemplary embodiments, in which

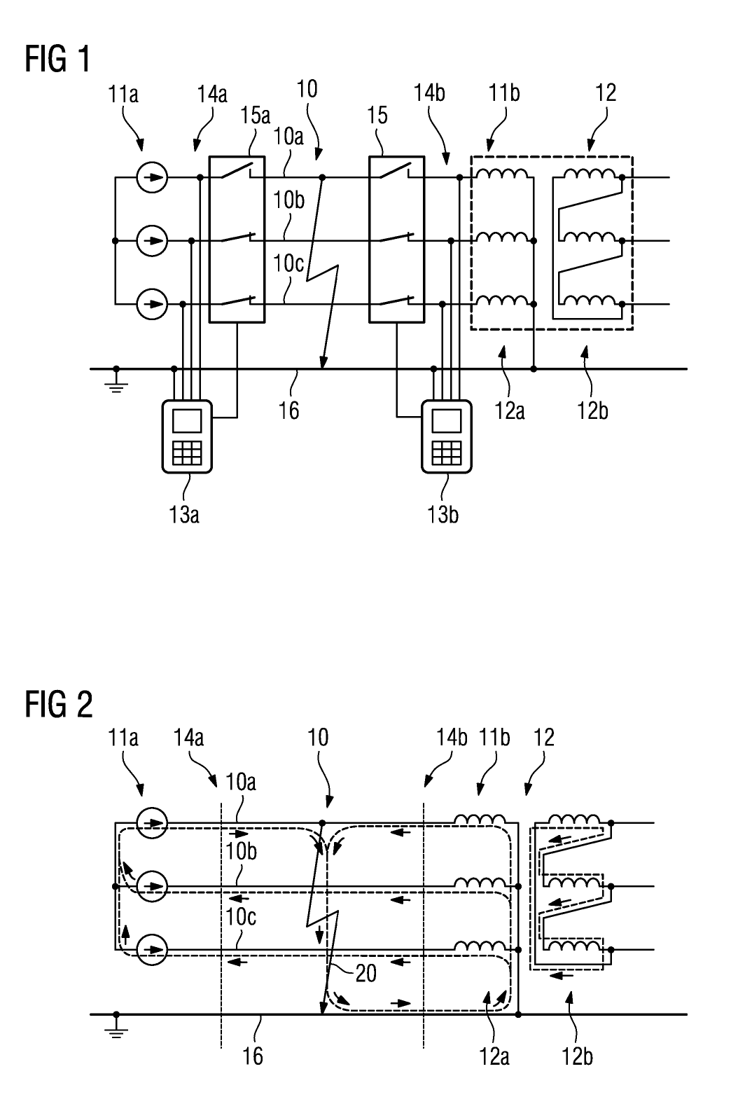

FIG. 1 shows a schematic view of a power supply line supplied on one side;

FIG. 2 shows a diagram of the current flow directions in the phase conductors of the power supply line for a single-pole short-to-ground;

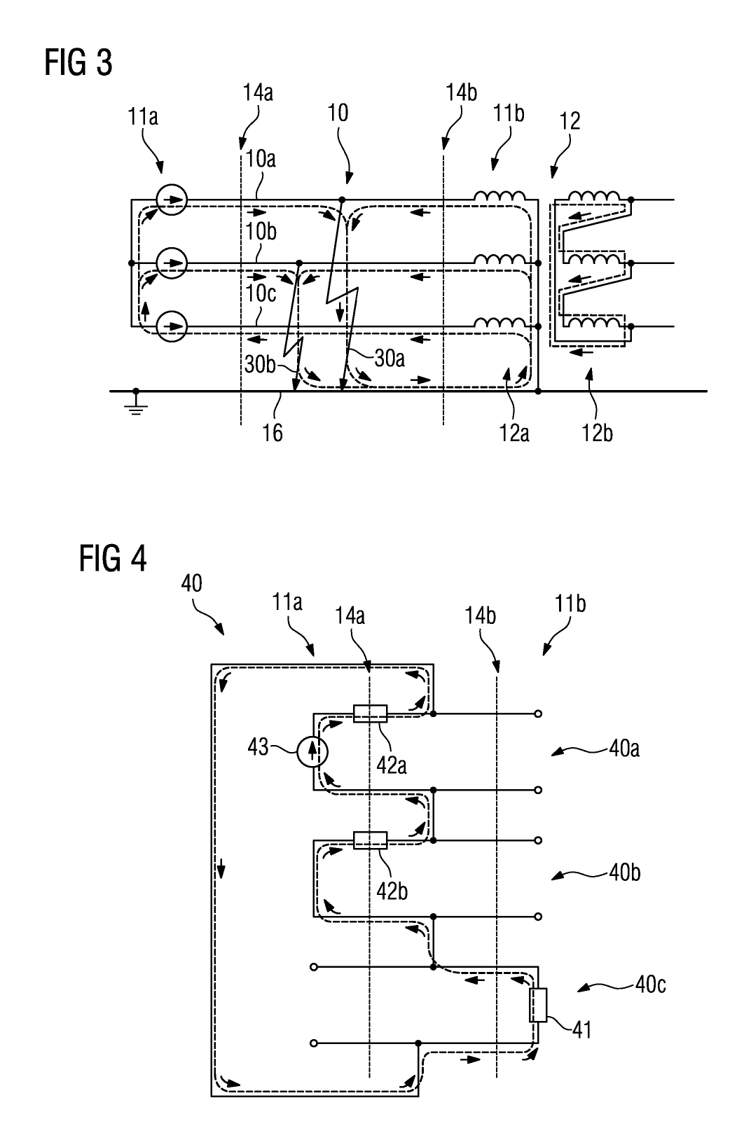

FIG. 3 shows a diagram of the current flow directions in the phase conductors of the power supply line for a two-pole short-to-ground;

FIG. 4 shows a diagram of the single-pole short-to-ground on the power supply line in symmetrical components;

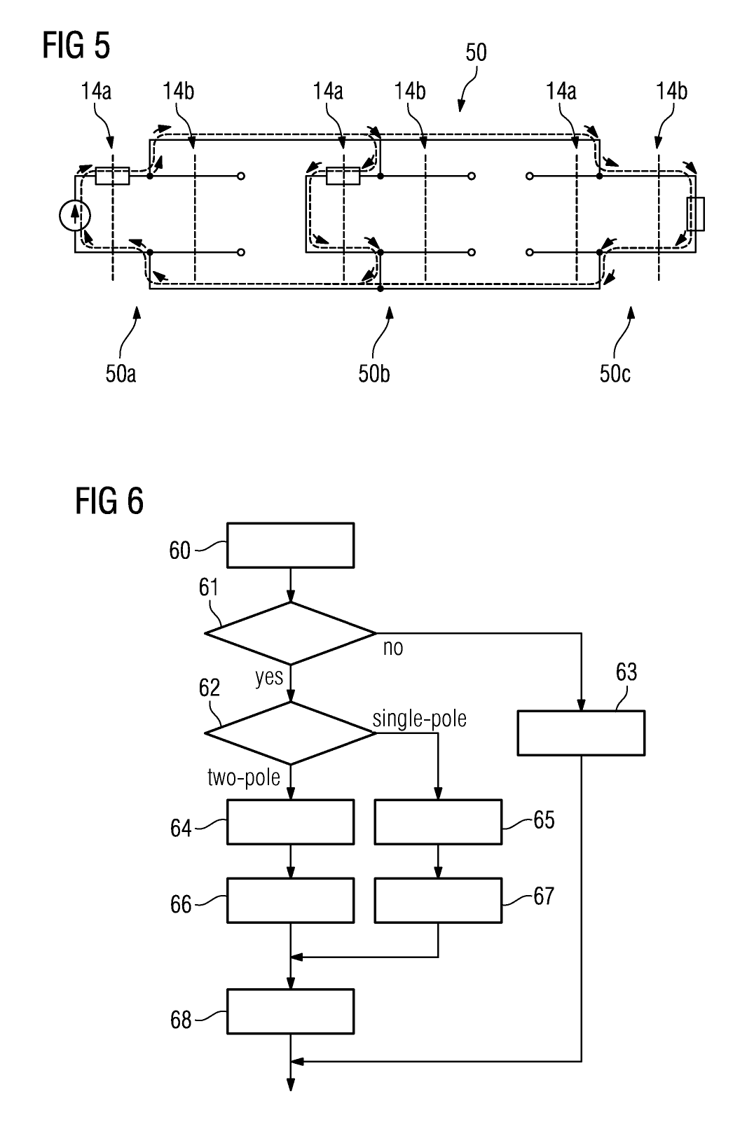

FIG. 5 shows a diagram of the two-pole short-to-ground on the power supply line in symmetrical components;

FIG. 6 shows a schematic flowchart of a method for detecting a short-to-ground in the power supply line; and

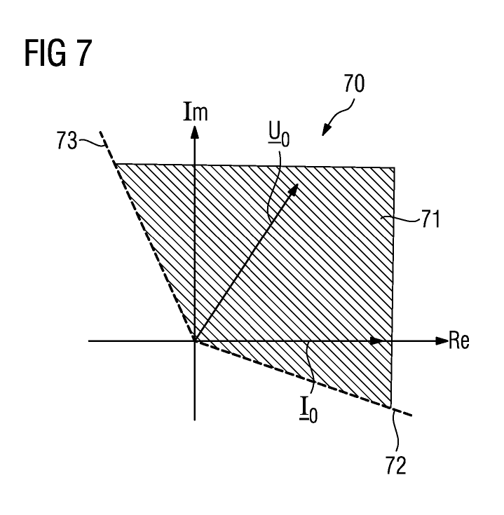

FIG. 7 shows a characteristic field for assessing the error direction of a short-to-ground.

In FIGS. 1 to 7 identical reference characters stand for components corresponding to one another.

FIG. 1 shows a schematic view of a three-phase electrical power supply line 10 of a power supply network otherwise not shown in any greater detail. The power supply line 10 has phase conductors 10a, 10b, 10c and is supplied from its one end 11a by an electric power source only indicated schematically. With its other end 11b, i.e. the end remote from the supply, the power supply line 10 is connected to a transformer 12 which is operated in a star-delta connection. This means that on the primary side 12a of the transformer the windings of the three-phase conductors 10a-c are combined in a star point with a common ground. On the secondary side 12b of the transformer the individual windings are each connected between two phase conductors.

The power supply line 10 is monitored for errors by means of protection devices 13a and 13b, which can involve distance protection devices for example, in particular a check is made as to whether one or more phase conductors 10a-c of the power supply line 10 has a short-circuit with ground contact, i.e. a short-to-ground. For this purpose the protection device 13a, at a measuring point 14a lying at one end 11a of the line, records measured values via current and voltage converters are only shown schematically in the diagram in relation to the phase currents and phase voltages, carries out an analog/digital conversion and if necessary further signal preprocessing and then evaluates the measured values using what are referred to as protection algorithms. In a corresponding way the protection device 13b, at a measuring point 14b lying at another end 11b remote from the supply, records measured values relating to the phase currents and phase voltages, carries out an analog/digital conversion and if necessary further signal preprocessing and then evaluates the measured values using the protection algorithms.

If an error, especially a short-to-ground, is identified on the power supply line 10 during the evaluation of the measured values by the protection devices 13a or 13b, an error signal is issued to a corresponding circuit breaker 15a, 15b, which by opening the corresponding switching contacts, switches off the phase conductor affected by the error, in the example shown in FIG. 1, the phase conductor 10a.

In the configuration shown in FIG. 1 of a power supply line 10 supplied on one side, with a transformer 12 connected thereto operated in a star-delta connection, in the event of single-pole (phase conductor—ground) or two-pole (phase conductor—phase conductor—ground) short circuits with connection to ground 16, the result can be the occurrence of Bauch's paradox, in which the error currents act by coupling on the secondary side 12b of the transformer 12 to the sound conductors of the primary side 12a.

The occurrence of Bauch's paradox is explained by the type of connection of the transformer 12 in the form of the star-delta connection as well as by the supply of electric energy into the power supply line 10 from only the end 11a of the power supply line 10, which is remote from the transformer 12. Its structure allows the transformer to transmit what are referred to as the zero sequence components of currents and voltages. For the zero sequence variables the concrete structure of the transformer 12 offers a relatively small internal zero sequence impedance, which is predominantly produced by the stray inductances of the transformer windings. The magnetization inductance can on the other hand be ignored here since it is much larger than the stray inductance and also is located in a parallel circuit to the stray inductances.

If the transformer 12 is operated non-symmetrically and with a detectable zero sequence voltage, as occurs in the case of a single or two-pole short-to-ground on the power supply line 10, then the zero sequence components occur in the current which flows in the transformer windings. The zero sequence current cannot be further transmitted beyond the secondary side 12b of the transformer 12 since the secondary delta circuit in the transformer 12, because of the lack of grounding does not make possible any outflow of the zero sequence currents. The zero sequence component in the voltage causes circulating currents in the star-delta-configuration windings of the secondary side 12b of the transformer 12, which are transmitted by a magnetic coupling of the two transformer sides to the primary side 12a of the transformer 12. Since the circulating currents on the secondary side 12b possess the same phase angle as well as the same amplitudes, they also cause similar conditions for the phase currents on the primary side 12a of the transformer 12, i.e. the phase currents on the primary side 12a of the transformer 12 have a matching phase angle and have the same amplitudes.

FIG. 2 shows a schematic of the current flow directions in the individual phase conductors 10a, 10b, 10c of the power supply line 10 and in the transformer 12 for a single-pole short-to-ground 20 between the phase conductor 10a and ground 16. For simplification it is assumed for the diagram shown in FIG. 2 that the power supply network is not grounded at the end 11a of the power supply line 10, into which the electric energy is supplied. The single-pole short-to-ground 20 leads, because of the electrically undesired connection of the phase conductor 10a to ground 16, to a phase-ground loop affected by an error being produced in which the short-circuit current driven by the voltage source of the supply, the direction of flow of which is shown by a dashed line in FIG. 2, flows with a very marked zero sequence component. Since the voltage source operates without grounding, the short-circuit current can only flow through the windings of the transformer 12 and not return through the phase conductors 10b and 10c not affected by the error to the energy source. Since the windings of the transformer 12 are coupled magnetically to one another, the currents flowing on the primary side 12a cause corresponding currents on the secondary side 12b and vice versa. The zero sequence current circulates in the star-delta winding on the secondary side 12b of the transformer 12 and induces corresponding currents on the primary side 12a of the transformer 12. It can be easily seen from FIG. 2 that, when the significant phase currents at the measuring point 14b at the end of the power supply line 10 remote from the supply are observed, in the actually sound phase conductors 10b and 10c two fictitious, phase-ground loops not involved in the short-circuit can be formed which are produced by the magnetic coupling between the windings of the transformer 12. These fictitious loops may not be included in the calculation of the protection algorithms.

FIG. 3 shows a schematic of the current flow directions in the power supply line 10 in the event of a two-pole short-to-ground, which is formed by the unwanted electrical connections 30a and 30b between the phase conductor 10a and ground 16 as well as the phase conductor 10b and ground 16. Like the single-pole short-to-ground shown in FIG. 2, circulating currents also occur here in the windings on the secondary side 12b of the transformer 12, which in their turn cause phase currents of the same size in relation to one another in the phase conductors 10a, 10b, 10c. In this case, from the standpoint of the protection device, a “fictitious”, phase-ground loop not involved in the short circuit (between the phase conductor 10c and ground 16) shows that the measuring point 14b, which is produced from the magnetic coupling between the windings of the transformer. Since a two-pole error is involved, this “fictitious” loop can lead to the incorrect triggering of the protection algorithm.

From the observation of the current flows in accordance with FIGS. 2 and 3 the conclusion can be drawn that the evaluation of the phase conductor-related currents is not sufficient for correct detection of a short-to-ground if Bauch's paradox is present. Therefore the symmetrical components must be included. For the two error types (single-pole or two-pole short-to-ground)) two different equivalent circuit diagrams must be created here in the form of symmetrical components.

FIG. 4 therefore shows an equivalent circuit diagram 40 with current flow indicated by a dashed line during a single-pole internal short-to-ground. The complete equivalent circuit diagram 40 is formed from three serially-connected part circuit diagrams, which can be considered separately for each symmetrical component. In concrete terms the equivalent circuit diagram 40 comprises a part circuit diagram 40a representing the positive sequence, a part circuit diagram 40b representing the negative sequence and a part circuit diagram 40c representing the zero sequence. For the consideration it has been assumed merely by way of example and non-restrictively that no grounding is present at the supply end 11a of the power supply line. Thus in part circuit diagram 40c no zero sequence current is to be expected at the measuring point 14a lying at this end 11a. By contrast, in the part circuit diagrams 40a and 40b positive sequence currents or negative sequence currents flow through the line impedances 42a, 42b.

The voltage source 43 is only contained in the part circuit diagram of the positive sequence.

The star-delta circuit transformer is connected to the other end 11b of the power supply line. The low zero sequence impedance 41 of the transformer causes the short-circuiting of the circuit with zero sequence visible in the part circuit diagram 40c. This contributes to the zero sequence current being able to flow through the zero sequence impedance 41. Since the short-to-ground is present on the power supply line, Bauch's paradox can only be detected at the measuring point 14b.

It emerges from the equivalent circuit diagram 40 that the flowing current at the measuring point 14b has neither a positive sequence nor a negative sequence component. If a load is connected to the transformer, then positive sequence and negative sequence components occur in the current, which however are much smaller than the zero sequence components, since a load impedance of the connected load is significantly larger than the zero sequence impedance of the transformer. For this reason the detection of Bauch's paradox is carried out on the basis of the zero sequence components.

FIG. 5 shows an equivalent circuit diagram 50 with the current flows in the event of a two-pole short-to-ground on the power supply line. The complete equivalent circuit diagram 50 is formed in this case from three parallel-connected part circuit diagrams. In concrete terms the equivalent circuit diagram 50 comprises a part circuit diagram 50a representing the positive sequence, a part circuit diagram 50b representing the negative sequence and a part circuit diagram 50c representing the zero sequence. In a similar way to the single-pole short-to-ground in accordance with FIG. 4, in the case of a two-pole short-to-ground no—or negligible compared to the zero sequence component—positive sequence and negative sequence components of the current are present at the measuring point 14b. This effect in its turn is included as a criterion for detecting Bauch's paradox.

Through the use of correspondingly adapted protection algorithms for monitoring the power supply line in respect of the presence of a short-to-ground it is possible also to deal with shorts-to-ground in which Bauch's paradox occurs and to switch off conductors selectively. In this case a multistage process takes place, essentially comprising the steps “detect the presence of Bauch's paradox”, “carry out an adapted loop selection” for detecting the loop subject to error, “carry out an adapted direction detection” for detecting the direction in which the short-to-ground lies, seen from the respective protection device. A description of the corresponding protection algorithm will now be provided with reference to the flow diagram shown in FIG. 6. In this case it is merely assumed by way of example, that the protection devices 13a and 13b executing the adapted protection algorithm (cf. FIG. 1) are distance protection devices which normally monitor the power supply line 10 for errors using a normal distance protection method. In addition to the distance protection algorithm, the adapted protection algorithm described below is implemented in the protection devices 13a, 13b, which only become effective when Bauch's paradox is detected.

The schematic execution sequence of the adapted protection algorithm is shown in FIG. 6. In a first step 60 in this sequence the required measured variables of the individual phase currents and phase voltages at the measuring point are accepted by the respective protection device. From said variables corresponding positive sequence, negative sequence and zero sequence variables are computed as part of the measured value processing.

In a further step 61a check is made on the basis of the accepted or computed measurement variables as to whether the effect of Bauch's paradox is present. To this end the respective protection device checks whether the individual phase currents and the zero sequence current are of roughly the same magnitude and are in phase and if necessary generates a suspected short-to-ground signal. For comparison of the variables of the phase currents and the zero sequence currents the zero sequence current must be considered in accordance with the following equation:

$${\underline{I}}_{0} = \frac{{\underline{I}}_{L 1} + {\underline{I}}_{L 2} + {\underline{I}}_{L 3}}{3} ,$$

wherein I₀ refers to a pointer variable of the zero sequence current and I_{L1}, I_{L2} and I_{L3} stand for the pointer variables of the individual phase conductor currents.

Since the numerical definition of the phase relationship of individual measurement variables to one another is frequently very complex, the checking of the above condition can be replaced by interrogation of the following two criteria:

In accordance with the first criterion the zero sequence current will be compared with the positive sequence current and also the negative sequence current. If the zero sequence current is significantly larger than the other two symmetrical current components, a first indicator signal is generated, which specifies that a Bauch's paradox could be present. In this case it is sufficient for only the amplitudes of the symmetrical components to be compared with one another:

|I₀|>>|I₁|,

|I₀|>>|I₂|

Wherein I₀, I₂ and I₂ refer to corresponding pointer values of the zero sequence current, the positive sequence current and the negative sequence current. To make the method robust in relation to measurement errors and to make possible a secure triggering in such cases during Bauch's paradox, the checking should be carried out using a factor k having a value significantly larger than 1:

|I₀|>k·|I₁|,

|I₀|>k·|I₂|

In accordance with the second criterion the zero sequence current is compared with the individual phase currents, and a second indicator signal is generated if the zero sequence current and the individual phase currents are approximately the same size. The comparison can be carried out on the basis of the amplitudes because the checking of the phase angle is already implicitly contained in the first criterion. In respect of the second criterion the following conditions are therefore checked:

kᵤ·|I_{L1}|>|I₀|>k₀·|I_{L1}|,

kᵤ·|I_{L2}|>|I₀|>k₀·|I_{L2}|,

kᵤ·|I_{L3}|>|I₀|>k₀·|I_{L3}|,

wherein kᵤ refers to a percentage lower limit and kₒ refers to a percentage upper limit for the triggering of the criterion. If both the first and also the second indicator signal are present the suspected short-to-ground signal is generated.

If in step 61, as described, the presence of Bauch's paradox is detected and the suspected short-to-ground signal is generated, then in step 62 a detection of the error type is carried out, i.e. whether the error involves a single-pole, or two-pole short-to-ground. Otherwise in step 63 the “normal” protection algorithm is operated, i.e. a distance protection algorithm for example.

The type of error is defined in step 62 by a comparison of the voltages of the positive sequence and the negative sequence. Starting from the equivalent circuit diagram for the two-pole short-to-ground (cf. FIG. 5) it can be very easily seen that, for this error type, negative sequence voltage and positive sequence voltage are equal in their amplitudes. Since however this is not yet a sufficient criterion for uniquely detecting the type of error, the phase angle of the two components to one another must also be analyzed in this test. The difference of the phase angle can theoretically possess three values for the two-pole error, depending on the reference phase: 0°, 120° or 240°. The difference formation between the positive sequence voltage and negative sequence voltage takes place here on the basis of the pointer values since it is not possible to derive the phase angle from the amplitudes. In this case one of the components in each case is rotated computationally by 120° and 240° in each case since the actual loop affected by the error is unknown and it is thus not certain which phase shift is actually present between the positive sequence voltage and negative sequence voltage. This computation consequently produces three differences, wherein only one corresponds to the actual error loop. If one of the differences formed amounts to 0, then a two-pole error is detected and an error type signal specifying a two-pole short-to-ground is formed. The logically ORed conditions checked for this are as follows:

|U₁−U₂|≈0 [symbol] |U₁−e^{j120°}·U₂|≈0 [symbol] |U₁−e^{j240°}·U₂|≈0

wherein U₀ is a zero sequence voltage, U₁ is a positive sequence voltage and U₂ is a negative sequence voltage. The exponential components e^{j120°} or e^{j240°} represent the mathematical rotation of the negative sequence voltage by the respective phase angle relative to the positive sequence voltage.

Since errors occur during the measurement or a load transmission can take place in the power supply network, the pointer differences between the positive sequence voltage and the negative sequence voltage can easily deviate from the ideal value of zero. For this reason, in the above equation, in practice instead of the value zero, a trigger threshold value is introduced, which allows the correct error type to be selected despite possible deviations. The trigger threshold value is dynamically dependent on the size of the negative sequence voltage and the positive sequence voltage. If one of these components increases then the trigger threshold value is dynamically increased:

S_{A}m·max(|U₁|, |U₂|)+M

In this case m is a predetermined percentage dependency factor and M is the constant threshold. The use of the dynamically-defined trigger threshold value enables the criterion to respond both at low and also at higher currents. If the difference between the positive sequence current and the negative sequence current fulfills the disclosed dynamic criterion, it is concluded that the error is the two-pole and the first error type signal is generated. Otherwise a single-pole error is detected and a second error type signal specifying a single-pole error is generated.

Depending on which error type has been detected, the loop affected by the error will be detected in a different way. If a two-pole short-to-ground is displayed by the first error type signal, in a following step 64 the chained voltages (i.e. the voltages existing between the respective phase conductors) are investigated and the two phase conductors are selected as affected by the two-pole short-to-ground of which the joint chained voltage is the lowest. The selected error loop is shown by the first loop selection signal. If on the other hand it is shown by the second error type signal that the error involved is a single-pole short-to-ground, in an alternate step 65 the respected phase voltages (i.e. the voltages between the respective phase conductor and ground) are investigated and that phase conductor which has the lowest phase voltage is selected as being affected by the single-pole short-to-ground. The selected error loop is shown by a second loop selection signal.

In the steps 66 or 67 which now follow the impedance of the error loop selected by the respective loop selection signal is investigated as to its position in an excitation region and a confirmation signal is generated if the impedance of the error loop lies within the trigger area. For this purpose the trigger areas usually used within the framework of a distance protection algorithm can be used to assess error loop impedances.

Only when the confirmation signal has been generated, i.e. the impedance of the selected error loop lies in the respective excitation region, will the direction in which the error lies, seen from the respective protection device, be investigated in a concluding step 68. In this case a forwards direction means the detection of an error from the direction of the monitored power supply line, while a backwards direction enables an external error outside the monitored line to be deduced. The direction detection is carried out independently of the type of error detected (single-pole or two-pole) in the case of Bauch's paradox not loop-oriented, but on the basis of the zero sequence variables, since the phase conductor-related measurement variables—as explained for FIGS. 4 and 5—would not deliver reliable results. To determine the error direction the pointer variables of zero sequence current and zero sequence voltage are considered. It is evident from the explanations provided for FIGS. 4 and 5 that the zero sequence variables can be essentially related back to the zero sequence impedance of the transformer. Since this impedance is inductive, it is to be expected that the zero sequence current in the event of a forwards error (i.e. of a short-to-ground lying on the line) lags behind the zero sequence voltage. For this reason a directional characteristic can be applied, as is shown by way of example in FIG. 7.

To this end, FIG. 7 shows a diagram 70 in the complex numerical plane, in which the real and imaginary part of the zero sequence components for current I₀ and voltage U₀ are shown. In this figure the pointer for the zero sequence current I₀ is mapped on the real axis and is used as reference pointer. For this purpose it must be rotated by 180°. Basically it is to be expected that with a forwards directed short-to-ground, both pointers, i.e. both for the zero sequence current rotated by 180° and also for the zero sequence voltage, lie in the first quadrant of the complex numerical plane. In order to also compensate for uncertainties as a result of measuring inaccuracies in this case, the directional characteristic is expanded accordingly by the boundary lines 72 and 73. For example these boundary lines can lie at −22° and +122°.

If a forwards error is detected in step 68 (cf. FIG. 7) a forwards signal is generated, through which the protection device is caused to issue an error signal which is output to the corresponding circuit breaker, 15a or 15b (cf. FIG. 1). If the error signal is present the circuit breaker opens its corresponding switching contact in order to disconnect the respective phase conductor affected by the error from the rest of the power supply network.

The described adapted protection algorithm allows a protection device, especially a distance protection device, even if the effect in accordance with Bauch's paradox is present, to correctly detect and switch off a short-to-ground. With the use of a distance protection device the high triggering speed of the distance contact can be fully utilized and all distance protection zones (excitation regions) can be used. In addition a false triggering of the distance protection device can be avoided by using the adapted protection algorithm instead of the usual distance protection algorithm if Bauch's paradox is present. The transformer at the end of the power supply line which, as explained, is involved during the error, can be effectively protected against thermal overloading and saturation.

The described adapted algorithm can be integrated relatively easily into protection devices, especially distance protection devices of any type, since all measurement variables to be used can be made available in any event.

1-10. (canceled)

11. A method of monitoring a power supply line of a three-phase electrical power supply network that is supplied at one end for the presence of a short-to-ground, wherein the power supply line is connected, at the end thereof remote from the supply, to a transformer operated in a star-delta connection, the method which comprises:
determining individual phase currents in individual phase conductors of the power supply line and a zero sequence current at a measurement point lying at the end of the power supply line remote from the supply;
generating a suspected short-to-ground signal if the individual phase currents and the zero sequence current are of a substantially equal magnitude and in phase; and
including the suspected short-to-ground signal in further monitoring in respect of the presence of the short-to-ground.

12. The method according to claim 11, which further comprises:
determining a positive sequence current and a negative sequence current at the measuring point and comparing the zero sequence current with the positive sequence current and with the negative sequence current and forming a first indicator signal if the zero sequence current exceeds both the positive sequence current and the negative sequence current by a predetermined factor;
comparing the zero sequence current with the individual phase currents and forming a second indicator signal if a magnitude of the zero sequence current and the individual phase currents is almost equal; and
generating the suspected short-to-ground signal if both the first indicator signal and also the second indicator signal are present.

13. The method according to claim 11, which comprises, if the suspected short-to-ground signal is present, to determine the phase conductor affected by the short-to-ground, carrying out a comparison of the pointers for the positive sequence voltage at the measuring point and the negative sequence voltage at the measuring point, and forming an error type signal pointing to a two-pole short-to-ground when the phase angle enclosed by the pointers amounts to around 0°, 120° or 240°, and otherwise forming a second error type signal pointing to a single-pole short-to-ground.

14. The method according to claim 13, which comprises also forming the first error type signal when the phase angle enclosed by the pointers for the positive sequence voltage and the negative sequence voltage deviates from a trigger threshold value of 0°, 120° or 240°, wherein the trigger threshold value depends dynamically on a level of the positive sequence voltage and the negative sequence voltage.

15. The method according to claim 13, which comprises:
if the first error type signal is present, comparing chained phase voltages of the individual phase conductors to one another and forming a first loop selection signal, which specifies those phase conductors which jointly form the lowest chained phase voltage as being affected by a two-pole short-to-ground; and
if the second error type signal is present, comparing phase-ground voltages of the individual phase conductors and forming a second loop selection signal, which specifies those phase conductors which have the lowest phase-ground voltage as being affected by a single-pole short-to-ground.

16. The method according to claim 11, which comprises:
in order to detect a direction in which the short-to-ground lies in relation to the measuring point, comparing the negative zero sequence current pointer and the associated zero sequence voltage pointer and generating a forwards signal specifying a short-to-ground in the forwards direction if the zero sequence voltage pointer lags behind the negative zero sequence current pointer by a phase angle with a predetermined difference value.

17. The method according to claim 16, which comprises, if the forwards signal is present, generating an error signal causing a switching off of the respective phase conductor affected by the short-to-ground.

18. The method according to claim 17, which comprises:
for a phase conductor-ground loop affected by the short-to-ground, determining an impedance pointer and investigating a position of the impedance pointer in a predetermined excitation region in a complex number plane;
generating a confirmation signal if the impedance pointer lies in the excitation region; and
generating the error signal for switching off the phase conductor affected by the short-to-ground only if the confirmation signal is also present.

19. The method according to claim 11, which comprises carrying out the method steps
the method is carried out by a distance protection device connected to monitor the power supply line using an error detection algorithm as a kind of distance protection, and if the suspected short-to-ground signal is present, blocking detection algorithms for detecting a loop affected by an error and an error direction, usually executed as part of the error detection algorithm executed by the distance protection device.

20. An electrical protection device for monitoring a power supply line of a three-phase electrical power supply network supplied at one end in respect of the presence of a short-to-ground, wherein the power supply line is connected, at an end thereof remote from the supply, to a transformer operated in a star-delta connection, comprising:
a measuring device for detecting phase currents and phase voltages at a measuring point at the end of the power supply line remote from the supply; and
a data processing device connected to said measuring device and configured for processing the phase currents and phase voltages and carrying out the method according to claim 11.
